(19) United States
(12) Patent Application Publication
(10) Pub. No.: US 2014/0076379 A1
(43) Pub. Date: Mar. 20, 2014

(54) CONCENTRATING SOLAR ENERGY COLLECTOR

(71) Applicants: Jason Christopher KALUS, San Francisco, CA (US); Nathan Beckett, San Leandro, CA (US); Adam Thomas Clavelle, San Francisco, CA (US)

(72) Inventors: Jason Christopher KALUS, San Francisco, CA (US); Nathan Beckett, San Leandro, CA (US); Adam Thomas Clavelle, San Francisco, CA (US)

(73) Assignee: Cogenra Solar, Mountain View, CA (US)

(21) Appl. No.: 13/619,952

(22) Filed: Sep. 14, 2012

(51) Int. Cl. H01L 31/052; F24J 2/04; F24J 2/12

(52) U.S. Cl. 136/246; 126/692; 126/694; 126/634

(57) ABSTRACT

Systems, methods, and apparatus by which solar energy may be collected to provide heat, electricity, or a combination of heat and electricity are disclosed herein.

### BACKGROUND

1. Field of the Invention

The invention relates generally to a solar energy collecting apparatus to provide electric power, heat, or electric power and heat, more particularly to a parabolic trough solar collector for use in concentrating photovoltaic systems.

2. Description of the Related Art

Alternate sources of energy are needed to satisfy ever increasing world-wide energy demands. Solar energy resources are sufficient in many geographical regions to satisfy such demands, in part, by photoelectric conversion of solar flux into electric power and thermal conversion of solar flux into useful heat. In concentrating photovoltaic systems, optical elements are used to focus sunlight onto one or more solar cells for photoelectric conversion or into a thermal mass for heat collection.

In an exemplar concentrating photolelectric system, a system of lenses and/or reflectors constructed from less expensive materials can be used to focus sunlight on smaller and comparatively more expensive solar cells. The reflector may focus the sunlight onto a surface in a linear pattern. By placing a strip of solar cells or a linear array of solar cells in the focal plane of such a reflector, the focused sunlight can be absorbed and converted directly into electricity by the cell or the array of cells. Concentration of sunlight by optical means can reduce the required surface area of photovoltaic material while enhancing solar-energy conversion efficiency as more electrical energy can be generated from such a concentrator than from a flat plate solar cell with the same surface energy. There are continued efforts to improve the performance, efficiency, and reliability of concentrating photovoltaic systems while also considering other variables such as the cost of manufacturing, ease of installation and the durability of such systems.

### SUMMARY

Systems, methods, and apparatus by which solar energy may be collected to provide electricity, heat, or a combination of electricity and heat are disclosed herein.

A solar energy collector includes one or more rows of solar energy reflectors and receivers with the rows arranged parallel to each other and side-by-side. Each row comprises one or more linearly extending reflectors arranged in line so that their linear foci are collinear, and one or more linearly extending receivers arranged in line and fixed in position with respect to the reflectors with each receiver located approximately at the linear focus of a corresponding reflector A support structure pivotably supports the reflectors and the receivers of the one or more such rows to accommodate rotation of the reflectors and the receivers about a rotation axis parallel to the linear focus of the reflectors in that row. In use, the reflectors and receivers are rotated about rotation axes on rotation shaft to track the sun such that solar radiation or light rays on the reflectors is directed and concentrated onto and across the receivers.

In one embodiment, a solar energy collector includes a linearly extending receiver, a reflector comprising a plurality of linear reflective elements with their long axes parallel to a long axis of the receiver arranged side-by-side on a reflector tray and aligned with respect thereto in a direction transverse to the long axis of the receiver, and fixed in position with respect to each other. A linearly extending support structure that accommodates movement of the receiver, rotation of the reflector, or rotation of the receiver and the reflector about an axis parallel to the long axis of the receiver. The reflector has a free state profile and the support structure comprises one or more reflector supports oriented transverse to the rotation axis. The reflector tray is securable to the reflector support in a profile different than the free state profile.

There are many advantages to a solar collector having a reflector tray with a free state profile that when secured is in a different profile. One advantage is a simple fabrication process using thinner materials that creates a support structure that is strong enough to support weaker reflective elements and yet flexible enough to be flexed into the desired shape during final installation. Another advantage is the cost savings realized by using flat segments of reflective elements as opposed to using more expensive curved mirrors.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C show front (FIG. 1A), rear (FIG. 1B) and side (FIG. 1C) views of an example solar energy collector.

FIG. 2 shows, in a perspective view, details of an example transverse reflector support mounted to a rotation shaft.

FIGS. 3A-3D show cross-sectional views of a reflector including an example of an alternative embodiment FIG. 3D.

FIGS. 4A-4D show the perspective views of reflector trays as they would transition to a mounted position on a transverse reflector support.

FIGS. 5A-5C show example geometries of reflective elements arranged end-to-end in a collector near gaps between the reflective elements.

FIG. 6 shows a cross-sectional view of reflectors arranged end-to-end and attached to a transverse reflector support as per one embodiment of the invention.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention, This description will clearly enable one skilled in the art to make and use the invention, and describes several embodiments, adaptations, variations, alternatives and uses of the invention, including what is presently believed to be the best mode of carrying out the invention.

As used in this specification and the appended claims, the singular forms “a,” “an,” and “the” include plural referents unless the context clearly indicates otherwise, Also, the term “parallel” is intended to mean “parallel or substantially parallel” and to encompass minor deviations from parallel geometries rather than to require that any parallel arrangements described herein be exactly parallel. Similarly, the term “perpendicular” is intended to mean “perpendicular or substantially perpendicular” and to encompass minor deviations from perpendicular geometries rather than to require that any perpendicular arrangements described herein be exactly perpendicular.

This specification discloses apparatus, systems, and methods by which solar energy may be collected to provide electricity, heat, or a combination of electricity and heat.

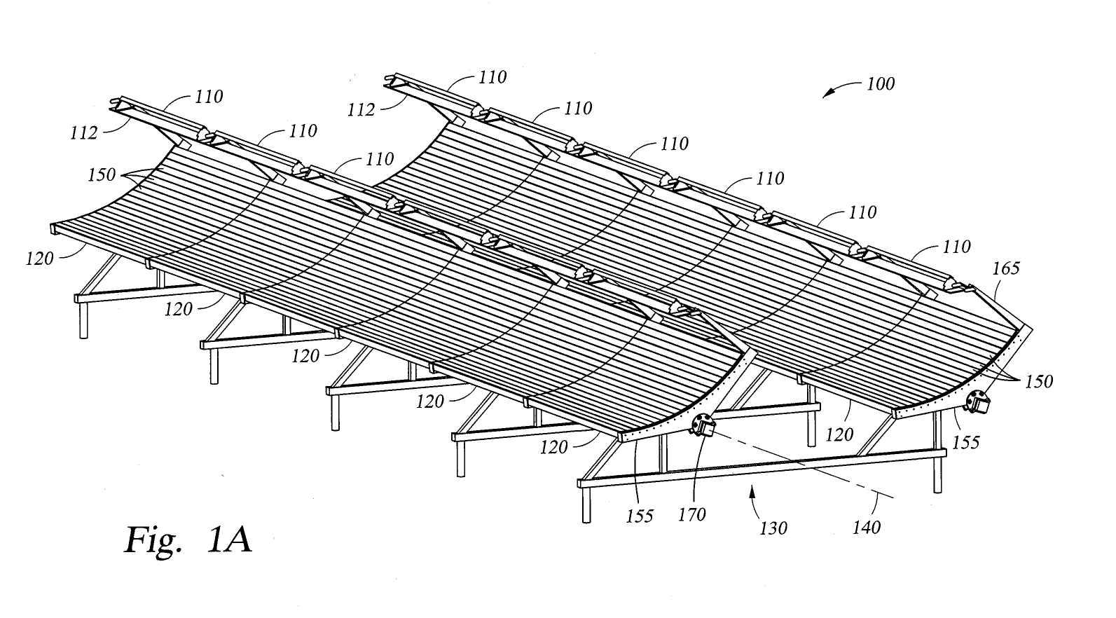

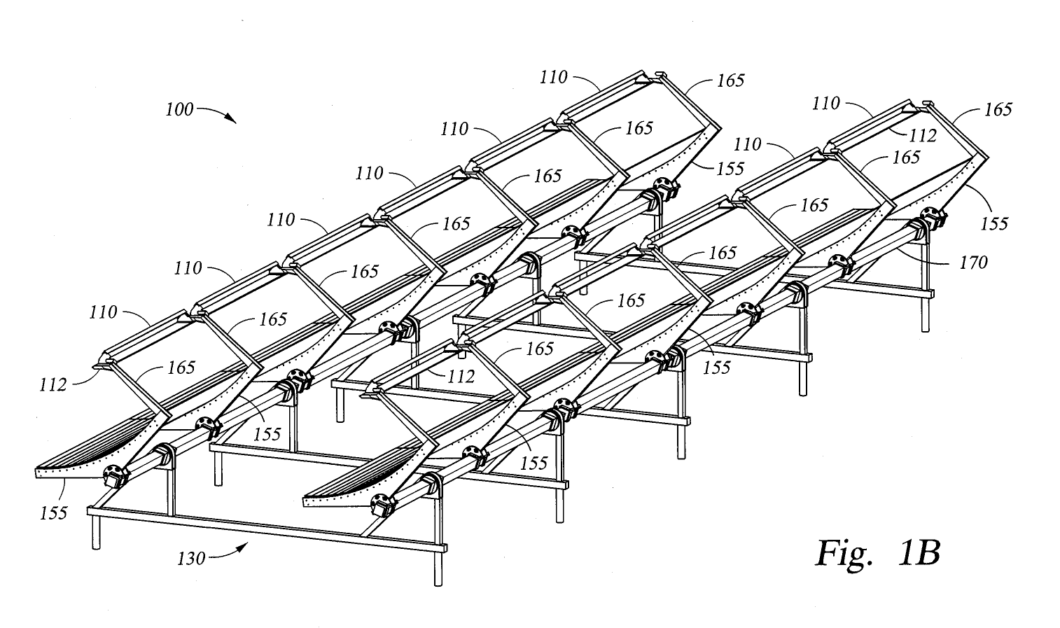

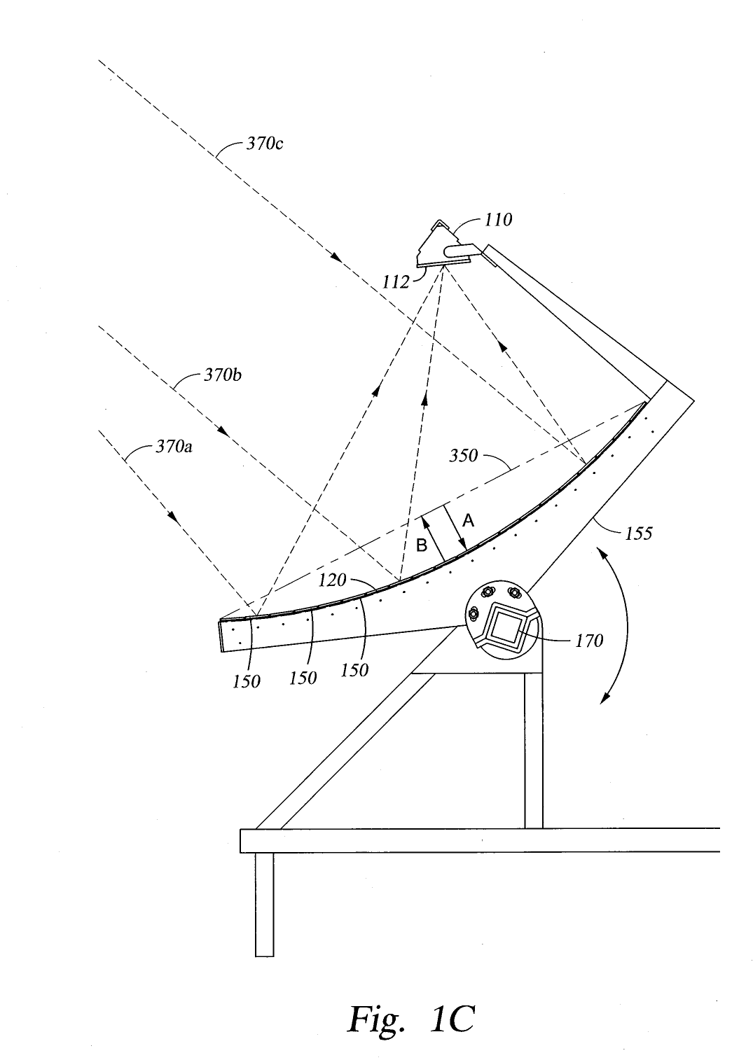

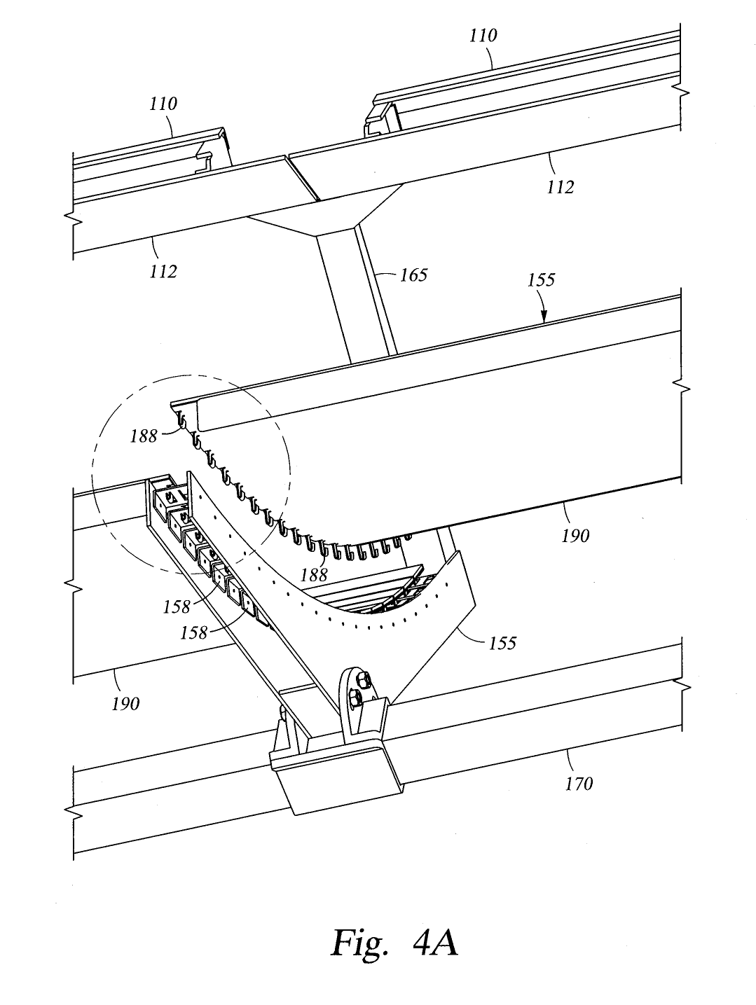

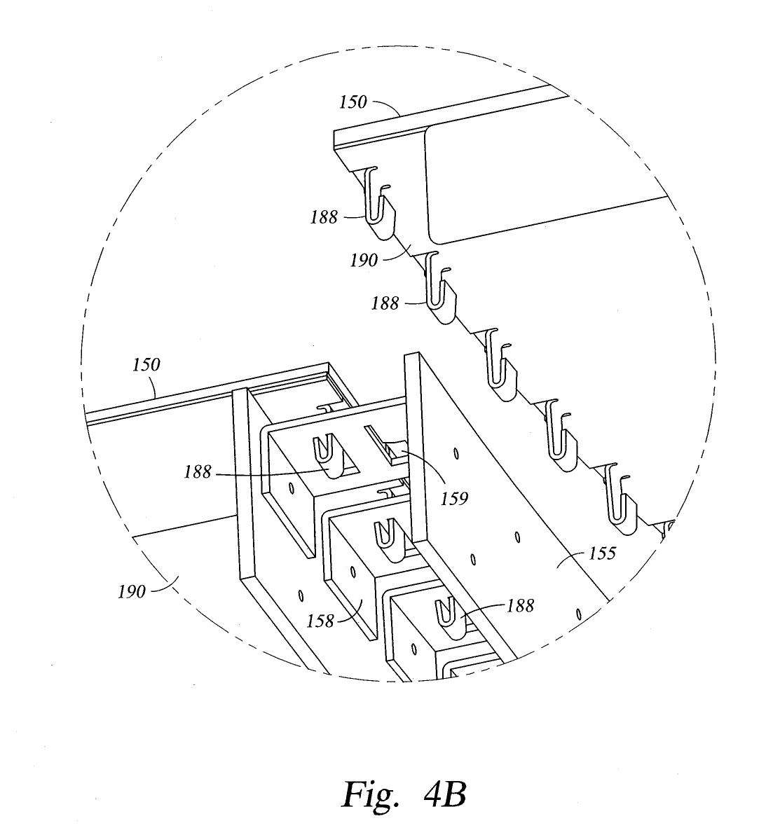

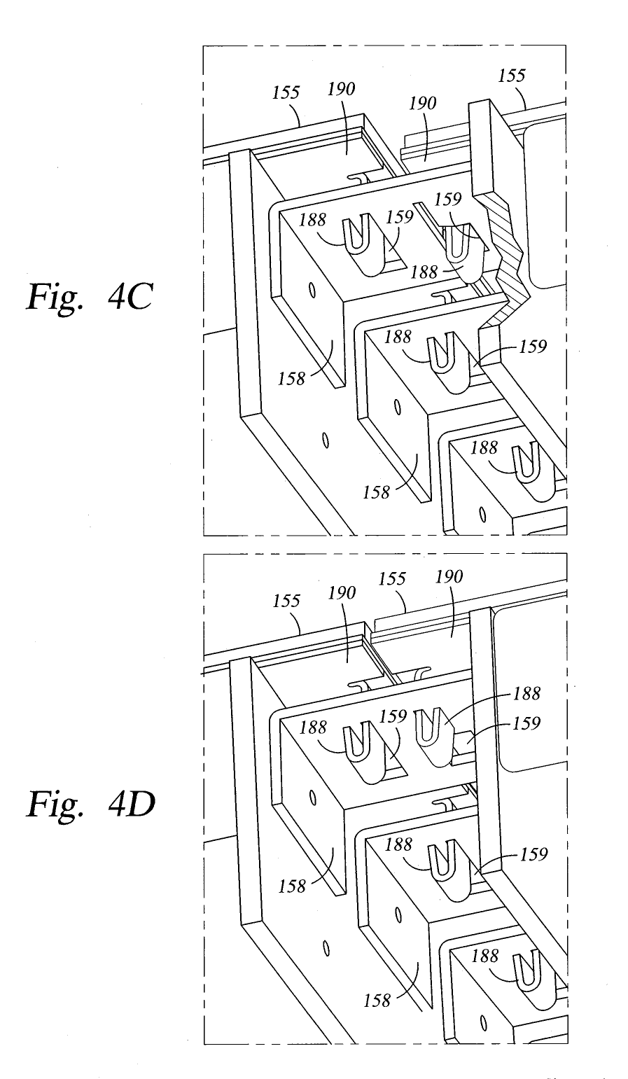

Referring now to FIGS. 1A, 1B and 1C, an example solar energy collector 100 comprises one or more rows of solar energy reflectors and receivers with the rows arranged parallel to each other and side-by-side. Each such row comprises one or more linearly extending reflectors 120 arranged in line so that their linear foci are collinear, and one or more linearly extending receivers 110 arranged in line and fixed in position with respect to the reflectors 120, with each receiver 110 comprising a surface 112 (FIG. 1A, 1C and FIG. 4A) located at or approximately at the linear focus of a corresponding reflector 120. A support structure 130 pivotably supports the reflectors 120 and the receivers 110 to accommodate rotation of the reflectors 120 and the receivers 110 about a rotation axis 140 parallel to the linear focus of the reflectors. In use, as illustrated in FIG. 1C, the reflectors 120 and receivers 110 are rotated about rotation axes 140 (best shown in FIG. 1A) on rotation shaft 170 to track the sun such that solar radiation (light rays 370a, 370b and 370c) on reflectors 120 is concentrated onto and across receivers 110, (i.e., such that the optical axes of reflectors 120 are directed at the sun).

In other variations, a solar energy collector otherwise substantially identical to that of FIGS. 1A and 1B may comprise only a single row of reflectors 120 and receivers 110, with support structure 130 modified accordingly.

As is apparent from FIGS. 1A and 1B solar energy collector 100 may be viewed as having a modular structure with reflectors 120 and receivers 110 having approximately the same length, and each pairing of a reflector 120 with a receiver 110 being an individual module. Solar energy collector 100 may thus be scaled in size by adding or removing such interconnected modules at the ends of solar energy collector 100, with the configuration and dimensions of support structure 130 adjusted accordingly.

Although each reflector 120 is parabolic or approximately parabolic in the illustrated example, reflectors 120 need not have a parabolic or approximately parabolic reflective surface. In other variations of solar energy collectors disclosed herein, reflectors 120 may have any curvature suitable for concentrating solar radiation onto a receiver.

In the example of FIGS. 1A, 1B and 1C, each reflector 120 comprises a plurality of linear reflective elements 150 (e.g., mirrors) linearly extended and oriented parallel to the linear focus of the reflector 120 and fixed in position with respect to each other and with respect to the corresponding receiver 110. As shown, linear reflective elements 150 each have a length equal or approximately equal to that of reflector 120 and are arranged side-by-side to form the reflector 120. In other variations, however, some or all of linear reflective elements 150 may be shorter than the length of reflector 120, in which case two or more linearly reflective elements 150 may be arranged end-to-end to form a row of linearly reflective elements 150 along the length of reflector 120, and two or more such rows may be arranged side-by-side to form a reflector 120. Typically, the lengths of linear reflective elements 150 are much greater than their widths. Hence, linear reflective elements 150 typically have the form of reflective slats.

In the illustrated example, linear reflective elements 150 each have a width of about 75 millimeters (mm) and a length of about 2751 mm. In other variations, linear reflective elements 150 may have, for example, widths of about 20 mm to about 400 mm and lengths of about 1000 mm to about 4000 mm. Linear reflective elements 150 may be flat or substantially flat, as illustrated, or alternatively may be curved along a direction transverse to their long axes to individually focus incident solar radiation on the corresponding receiver. Although FIG. 1C shows light rays 370a, 370b and 370c all converging on at a singled point on surface 112 of receiver 110, the figures are for illustrative purposes only and not to be limiting. One skilled in the art would understand that the flat surface of linear reflective elements 150 directs the focus of the incident solar radiation uniformly across the across the flat surface 112 of receiver 110 resulting in an equal dispersion of the incident solar radiation across receiver 110 providing a more efficient use of the solar cell positioned thereon.

Although in the illustrated example each reflector 120 comprises linear reflective elements 150, in other variations a reflector 120 may be formed from a single continuous reflective element, from two reflective elements, or in any other suitable manner.

Linear reflective elements 150, or other reflective elements used to form a reflector 120, may be or comprise, for example, any suitable front surface mirror or rear surface mirror. The reflective properties of the mirror may result, for example, from any suitable metallic or dielectric coating or polished metal surface.

In variations in which reflectors 120 comprise linear reflective elements 150 (as illustrated), solar energy collector 100 may be scaled in size and concentrating power by adding or removing rows of linear reflective elements 150 to or from reflectors 120 to make reflectors 120 wider or narrower. In another embodiment, two or more reflectors 120 with an appropriate number of linear reflective elements 150 may be placed side-by-side across the width of support structure 130 transverse to the optical axis of reflectors 120, and the width and length of transverse reflector supports 155 (discussed below), may be adjusted accordingly.

Referring again to FIGS. 1A, 1B and 1C, each receiver 110 may comprise solar cells (not shown) located, for example, on receiver surface 112 (best shown in FIG. 1C and FIG. 4A) to be illuminated by solar radiation concentrated by a corresponding reflector 120. In such variations, each receiver 110 may further comprise one or more coolant channels accommodating flow of liquid coolant in thermal contact with the solar cells. For example, liquid coolant (e,g., water, ethylene glycol, or a mixture of the two) may be introduced into and removed from a receiver 110 through manifolds (not shown) at either end of the receiver located, for example, on a rear surface of the receiver shaded from concentrated radiation. Coolant introduced at one end of the receiver may pass, for example, through one or more coolant channels (not shown) to the other end of the receiver from which the coolant may be withdrawn. This may allow the receiver to produce electricity more efficiently (by cooling the solar cells) and to capture heat (in the coolant). Both the electricity and the captured heat may be of commercial value.

In some variations, the receivers 110 comprise solar cells but lack channels through which a liquid coolant may be flowed. In other variations, the receivers 110 may comprise channels accommodating flow of a liquid to be heated by solar energy concentrated on the receiver, but lack solar cells. Solar energy collector 100 may comprise any suitable receiver 110. In addition to the examples illustrated herein, suitable receivers may include, for example, those disclosed in U.S. patent application Ser. No. 12/622,416, filed Nov. 19, 2009, titled “Receiver For Concentrating Photovoltaic-Thermal System;” and U.S. patent application Ser. No. 12/774,436, filed May 5, 2010, also titled “Receiver For Concentrating Photovoltaic-Thermal System;” both of which are incorporated herein by reference in their entirety.

Referring again to FIGS. 1A, 1B and 1C as well as to FIG. 2, in the illustrated example support structure 130 comprises a plurality of transverse reflector supports 155 and reflectors 120, which together support linear reflective elements 150. Each transverse reflector support 155 extends curvelinearly and transversely to the rotation axis 140 of the reflector 120 it supports. The reflector 120 supports a plurality of linear reflective elements 150 positioned side-by-side, or rows of linear reflective elements 150 arranged end-to-end, and extends parallel to the rotation axis of the reflector 120.

Support structure 130 also comprises a plurality of receiver supports 165 each connected to and extending from an end, or approximately an end, of a transverse reflector support 155 to support a receiver 110 over its corresponding reflector 120. As illustrated, each reflector 120 is supported by two transverse reflector supports 155, with one transverse reflector support 155 at each end of the reflector 120. Similarly, each receiver 110 is supported by two receiver supports 165, with one receiver support 165 at each end of receiver 110. Other configurations using different numbers of transverse reflector supports per reflector and different numbers of receiver supports per receiver may be used, as suitable. The arrangement of receiver supports 165 and reflector supports 155 is configured to enable the receivers 110 to be positioned at the concentration focal plane of the reflectors.

In the illustrated example and referring to FIGS. 1C and 2, each of the transverse reflector supports 155 is attached to a rotation shaft 170 which provides for common rotation of the reflectors and receivers in that row about their rotation axis 140 (FIG. 1A), which is coincident with rotation shafts 170, (i.e., the reflectors and receivers are fixed relative to each other, but their position vis-á-vis the supporting surface on which they are located can change to cause the reflectors to maintain an optimal position with respect to the changing position of the sun). Rotation shafts 170 are pivotably supported by slew posts and bearing posts. In other variations, any other suitable rotation mechanism may be used.

In the example shown in FIG. 2, transverse reflector support 155 is attached to rotation shaft 170 with a two-piece clamp 157. Clamp 157 has an upper half attached (for example, bolted) to transverse reflector support 155 and conformingly fitting an upper half of rotation shaft 170. Clamp 157 has a lower half that conformingly fits a lower half of rotation shaft 170. The upper and lower halves of clamp 157 are attached (for example, bolted) to each other and tightened around rotation shaft 170 to clamp transverse reflector support 155 to rotation shaft 170. Rotation shaft 170 is illustrated as a square shaped shaft, but in practice different shapes may be used including round or oval, or any other suitable linear support structure such as a truss. In some variations, the rotational orientation of transverse reflector support 155 may be adjusted with respect to the rotation shaft by, for example, about +/−5 degrees. This may be accomplished, for example, by attaching clamp 157 to transverse reflector support 155 with bolts that pass through slots in the upper half of clamp 157 to engage threaded holes in transverse reflector support 155, with the slots configured to allow rotational adjustment of transverse reflector support 155 prior to the bolts being fully tightened.

In the illustrated example, the upper portion of the side wall of the transverse reflector supports 155 have any curvature suitable (i.e., a parabola) for concentrating solar radiation reflected from the reflectors 120 mounted thereon to receiver 110. Additionally, the side walls of the transverse reflector support 155 extend above crossbars 158 positioned between the side walls. The crossbars 158 of the transverse reflector support 155 each sit below the top level of the side walls and have two parallel openings (e.g., slots, holes, channels) 159 arranged side-by-side. The crossbars 158 are positioned, and thus the openings 159 in crossbars 158 are positioned, to correspond with attachment mechanisms of the reflector 120 at appropriate positions along the length of the transverse reflector support 155 creating two aligned rows of openings 159 positioned along the length of the transverse reflector support 155. In the illustrated example, the spacing between the two rows of openings 159 is about 5 mm to 10 mm. In other variations, the two rows of projections may be spaced apart from each other by, for example, about 5 mm to 100 mm.

Typically one sidewall of a single transverse reflector support 155 supports one end of a first reflector 120 and the opposing sidewall supports the adjacent end of another reflector 120 where the two reflectors 120 are arranged linearly end-to-end. The transverse reflector support 155 that supports the edge of each reflector 120 positioned at each end of the collector 100 may be adjusted to have one row of openings (not shown).

In the illustrated example, the curved upper sidewall surfaces of transverse reflector support 155 provide reference surfaces that orient reflectors 120, and thus the linear reflective elements 150 they support, in a desired orientation with respect to a corresponding receiver 110 with a precision of: for example, about 0.5 degrees or better (i,e., tolerance less than about 0.5 degrees). In other variations, this tolerance may be, for example, greater than about 0.5 degrees.

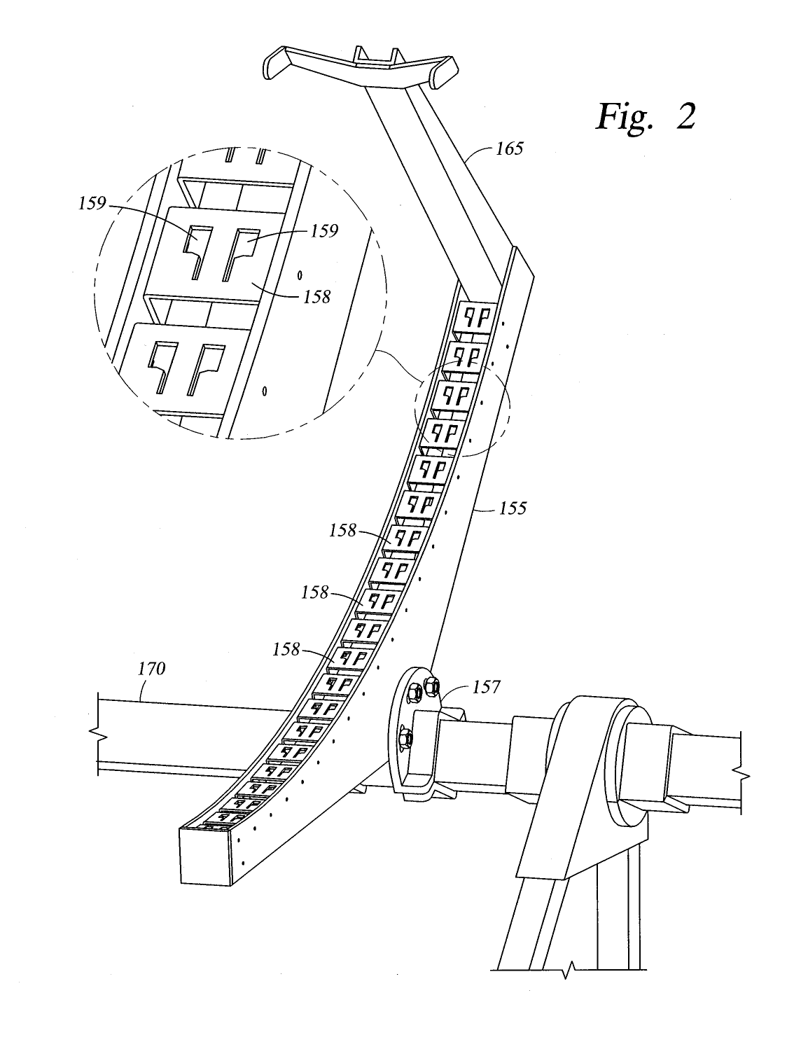

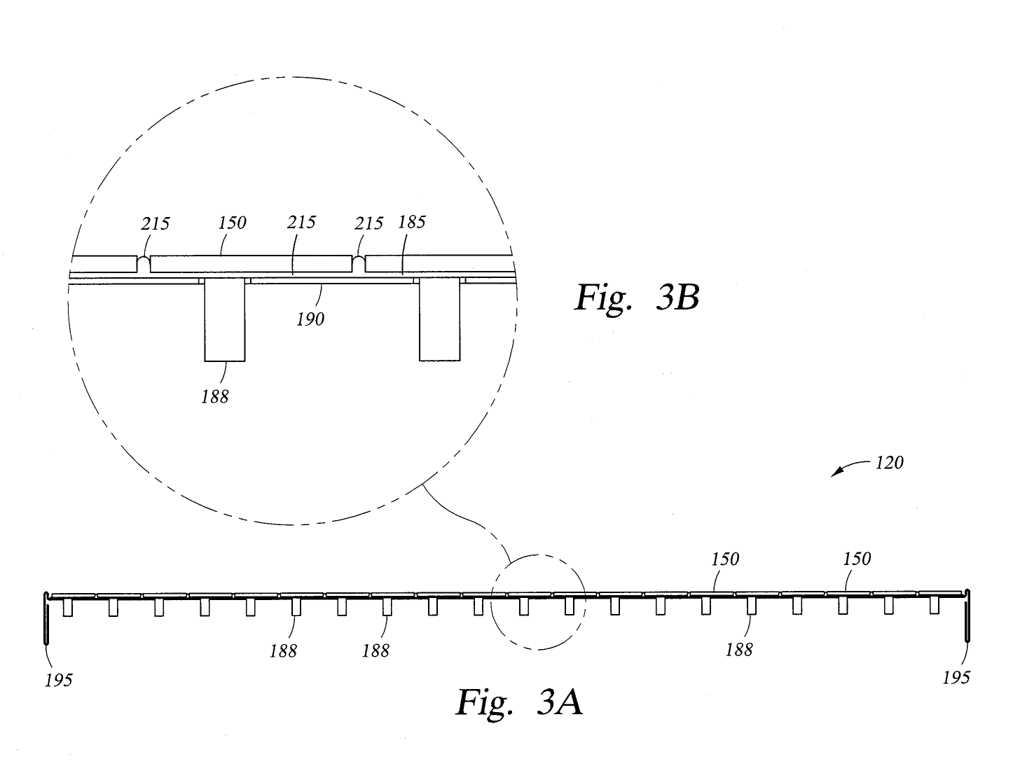

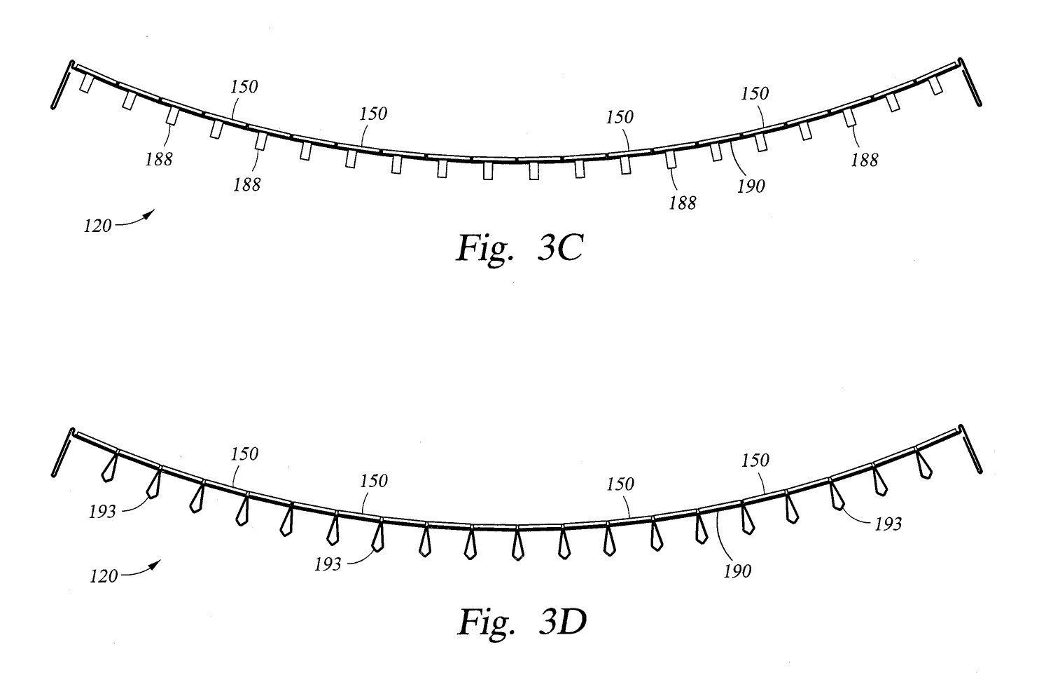

FIGS. 3A, 3B and 3C show a cross-sectional view of an example reflector 120 taken perpendicularly to its long axis. In the illustrated example, reflector 120 has a reflector tray 190 comprising an upper tray surface 185, tray side walls 195, tabs 188 and longitudinal support frames (not shown). Linear reflective elements 150 are positioned side-by-side on the upper tray surface 185 of reflector tray 190. The linear reflective elements 150 are positioned side-by-side such that a small gap extends the length of reflector 120 between each of the reflective mirror elements 150 (as shown in FIG. 1).

In the illustrated example, reflector tray 190 is about 2440 mm long and about 1540 mm wide (sized to accommodate 20 linear reflective elements). In other variations, reflector tray 190 is about 1000 mm to about 4000 mm long and about 300 mm to about 800 mm wide.

Referring to FIG. 3B, each linear reflective element 150 is held in place on the upper tray surface 185 with glue or other adhesive 215. The adhesive 215 coats the entire upper tray surface 185 and thus coats the complete underside of the linear reflective elements 150. Any other suitable method of attaching the linear reflective element 150 to the reflector tray 190 may be used, including adhesive tape, screws, bolts, rivets, clamps, springs and other similar mechanical fasteners, or any combination thereof.

In addition to attaching linear reflective elements 150 to upper tray surface 185, in the illustrated example adhesive 215 positioned between the outer edges of the rows of linear reflective elements 150 and between the outer edges of the linear reflective element 150 the tray side walls 195 may also seal the edges of the linear reflective elements 150 and thereby prevent corrosion of linear reflective elements 150. This may reduce any need for a sealant separately applied to the edges of the linear reflective elements 150. Adhesive 215 positioned between the bottom of the linear reflective element 150 and upper tray surface 185 may mechanically strengthen the linear reflective element 150 and also maintain the position of linear reflective elements 150 should they crack or break. Further, reflector tray 190 together with adhesive 215 may provide sufficient protection to the rear surface of the linear reflective element 150 to reduce any need for a separate protective coating on that rear surface often required during manufacturing

The reflector tray 190 to which the linear reflective elements 150 are adhered is made of sheet metal or other similar material with elastic properties and a thickness that allows the reflector tray 190 to flex and bend into a position matching the curvature of the transverse reflector support 155 forming a parabolic shape or similarly suited curve. The reflector tray 190 will bend between the mirrors as the stiffness of the combination of the metal of the reflective tray 190 and the reflective mirror elements 155 is greater than the stiffness of the metal alone. The flexible properties of reflective tray 190 allows the reflector 120 to be manufactured by adhering the linear reflective elements 150 to a flat surface that can be easily shipped and subsequently bent into its final shape in the field during the assembly of collector 100. Referring back to FIG. 1C, during assembly a flat reflector 120 is positioned in a free state profile at load plane 350 and a force (arrow A) is applied to deflect or bend reflector 120 to conform to and against the curvature of transverse reflector support 155. Because of the inherent elastic properties of the reflector tray 190, once the reflector 120 is securely attached to the transverse reflector support 155, a restoring force (arrow B) assists in providing and maintaining structural strength to the reflector 120. In addition, the flexible nature of the reflector 120 materials will help prevent warping of reflector 120 (and breaking of linear reflective elements 150) if materials with a different coefficient of thermal expansion are used for transverse reflector support 155 than the materials used for reflector tray 190.

FIG. 3D shows an alternative reflector 120 embodiment that includes a reflector tray 190 made of one continuous sheet of material with formed flexible angled sections 193 configured to extend the length of reflector tray 190 and positioned along the gaps that extend the length of reflector tray 190. The formed flexible angled sections 193 provide for greater flexibility of the reflector tray 190 and allows for the use of a thicker and less elastic materials. The formed flexible angles 193 should not be limited to the shape illustrated in FIG. 3D and can take any suitable shape that provides flexibility to reflector tray 190 at the positions of the formed flexible angled sections 193. An additional alternative embodiment of reflector 120 includes a reflector tray 190 with scores, creases or other means to selectively weaken the reflector tray material, lengthwise along the gaps between the mirrors, which subsequently allow the reflector tray 190 to bend to match the curvature of the transverse reflector support 155 when pressed in to place during assembly.

Tabs 188 as shown in FIGS. 3A, 3B and 3C and in greater detail in FIG. 4A-4D are attached to the reflector tray 190 of reflector 120 and are positioned such that tabs 188 correspond to the openings in transverse reflector support 155. Tabs 188 are suitably shaped (in the embodiment of FIG. 4A shaped as a hook) to slide into the openings 159 and hold the reflector 120 in place in a self-locking manner. The openings 159 may have self-aligning shape that directs the tab 188 and the reflector tray 190 into the proper position. The thickness and material from which the tab 188 is formed are chosen such that the tab has sufficient elasticity to flex during installation as it is placed into the opening in the transverse reflector support 155 and then provide for a restoring force that will engage with a horizontal underside portion of crossbar 158 of the transverse reflector support 155 with sufficient rigidity to hold reflector 120 in place. The flexibility of tab 188 eliminates complications during installation if openings 159 are somewhat offset either from a manufacturing error or from thermal expansion in the field during setup. A tab 188 exhibiting this self-locking feature may be provided, for example, by folding, or otherwise forming a sheet of pre-galvanized steel having a thickness of about 0.5 mm into the illustrated shape.

More generally, tabs 188 may snap-on to transverse reflector supports 155 through the engagement of any suitable complementary interlocking features on tray bottom 190 and transverse reflector support 155. Slots and hooks, protrusions and recesses, or louvers and tabs, or other mechanical fasteners attached to tray bottom 190 for example, may be used in other variations. The snap-on feature of tabs 188 to transverse reflector support 155 also eliminates the need for dealing with bolt/hole alignment issues in the field.

Referring back to FIG. 1A, reflectors 120, comprising linear reflective elements 150, are arranged linearly end-to-end across the length of the collector 100. Gaps are created between the ends of linear reflective elements 150 for each of the reflectors 120. These gaps between reflectors 120 in the solar energy collector 100 may cause shadows that produce non-uniform illumination of the receiver and have a negative effect on the efficiency of the receiver and significantly reduce the power output of collector 100.

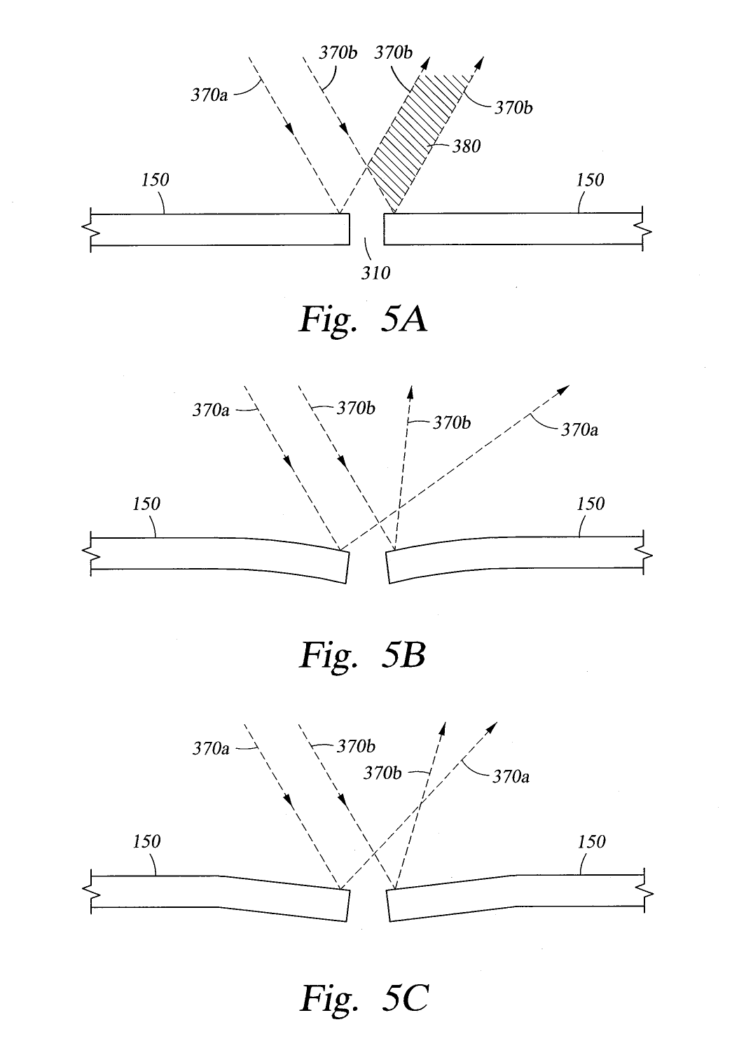

Referring to FIG. 5A, for example, shows light rays 370a, 370b incident on ends of linear reflective elements 150 adjacent to gap 310 are reflected in parallel and hence cast a shadow 380 because no light is reflected from the gap 310. In some embodiments, (not shown) where glass mirrors are used as the linear reflected elements 150, the light rays go through the glass portion of the mirror to the reflective surface below and are reflected back through the glass directed at the receiver 110. For those light rays that enter the top portion of the glass near the edge portions of the glass at gap 310 would otherwise be reflected towards the reflector 100, but due to the proximity of the light rays to the side edge of the glass are actually directed through the side edge of the glass along gap 310. These light rays scatter as they exit the side edge of the glass thereby further widening shadow 380. In some variations, such shadows may be attenuated, blurred or smeared by shaping the ends of reflective elements 150 adjacent the gap to spread reflected light into what would otherwise be a shadow.

Referring to FIGS. 5B and 5C, for example, ends of reflective elements 150 adjacent the gap may curve or bend down into the gap 310 (i.e., way from the incident). In such variations, light rays 370a, 370b are reflected in a crossing manner that spreads reflected into what would otherwise be a shadow 380 (FIG. 5A). Such shaping of the ends of linear reflective elements 150 may be accomplished, for example, by positioning underlying support structure such that a force draws the end of the reflective elements into the desired shape.

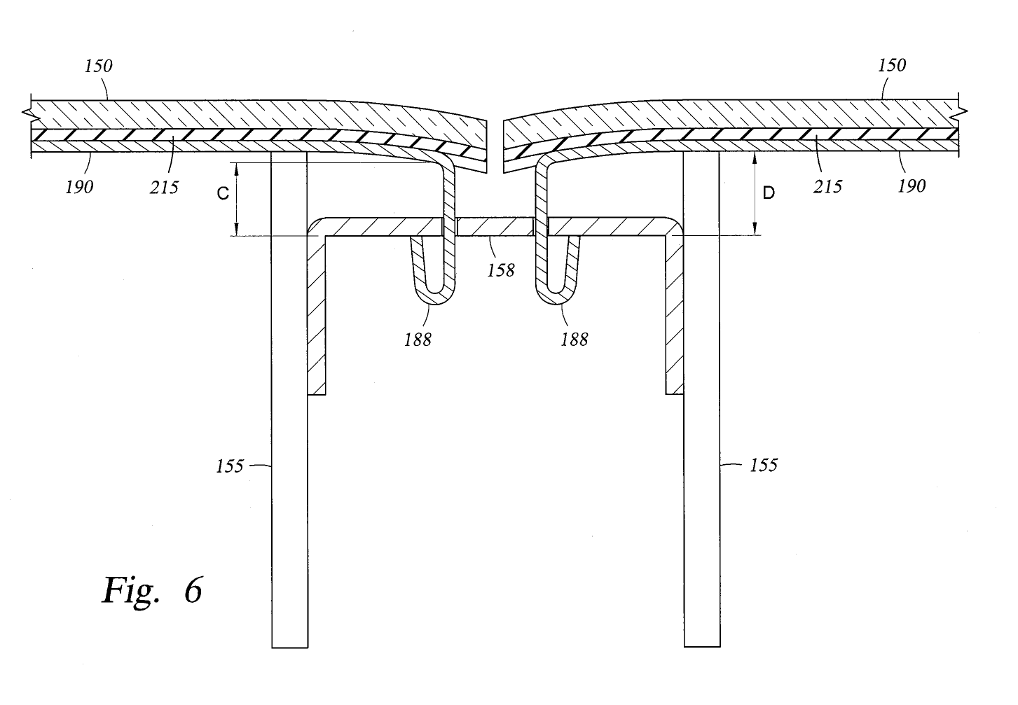

For example, as shown in FIG. 6, linear reflective element 150 is attached to reflector tray 190 with a portion of the linear end of reflector tray 190 positioned to extend over the sidewall of transverse reflector support 155. The tab 188 once positioned in the opening provides a force that pulls the cantilevered edge portion of the reflector tray 190 that extends over the sidewall downward. Because the linear reflective element 150 is adhered to the reflector tray 190, any deflection of the reflector tray 190 produces a deflection of the edge of the linear reflective element 150. Arrows C and D in FIG. 6 illustrate this point. Arrow D refers to a location outside transverse reflector support 155 and denotes a distance from the bottom surface of reflector tray 190 and a point on the sidewall of transverse reflector support 155 equivalent to the bottom side of the horizontal portion of crossbar 158 (the point where the tip of the hook of tab 188 engages crossbar 158). Arrow C refers to a location within the sidewalls of transverse reflector support 155 and denotes a distance from the cantilevered lower edge of reflector tray 190 to the tip of the hook of tab 188 which where the tip of hook 188 engages the crossbar. The distance of arrow C is less than the distance of arrow D because, by design, the tip of the hook of tab 188 is at a distance from the bottom surface of the reflector tray 190 that is less than the distance from the top of the sidewall (where the reflector tray 190 contacts the transverse reflector support 155) to the bottom of the horizontal portion of crossbar 158 thereby creating a pulling force between the crossbar 158 and the reflector tray 190 vis-a-vis tab 188. Positioning tab 188 within the opening within crossbar 158 causes downward deflection of the cantilevered edge of reflector tray 190. In some variations, receiver 110 is positioned approximately 1 meter from reflector 120 and the cantilevered edge is deflected to approximately a 0.33 degree angle to eliminate the shadow 380 (FIG. 5A). As an example, the cantilevered edge of reflector tray 190 as shown in FIG. 6 may be approximately 25 mm in length. To achieve a 0.33 degree angle the cantilevered portion of reflector tray 190 would be deflected downwards 0.15 mm. In an additional embodiment, slits (not shown) of a suitable length positioned at the edge of the reflector tray 190 that align and coincide with the gaps formed lengthwise between the side-by-side arranged linear reflective elements 150 may be added to reduce the amount of force necessary to bend the sheet metal material and the linear reflective element into the desired position. Alternatively, any suitable manner of shaping the ends of reflective elements 150 to attenuate shadows cast by gaps between the reflective elements may be used.

Where not otherwise specified, structural components of solar energy collectors disclosed herein may be formed, for example, from 20 gauge G90 sheet steel, or from hot dip galvanized ductile iron castings, or from galvanized weldments and thick sheet steel.

This disclosure is illustrative and not limiting. Further modifications will be apparent to one skilled in the art in light of this disclosure and are intended to fall within the scope of the appended claims. All publications and patent application cited in the specification are incorporated herein by reference in their entirety.

While the foregoing is directed to embodiments of the present invention, other and further embodiments of the invention may be devised without departing from the basic scope thereof, and the scope thereof is determined by the claims that follow.

1-12. (canceled)

13. A reflector for a solar energy collector comprising;
a flexible reflector tray; and
a plurality of flat linear reflective elements each having a long axis,
wherein the linear reflective elements are arranged on the reflector tray side-by-side with their long axes parallel and with gaps between adjacent linear reflective elements extending parallel to the long axes of the linear reflective elements; and
wherein the reflector tray bends along the gaps between the linear reflective elements, and the linear reflective elements remain flat, when the reflector is bent for positioning in the solar energy collector.

14. The reflector of claim 13, wherein the plurality of linear reflective elements is adhered to the reflector tray with an adhesive.

15. The reflector of claim 14, wherein the adhesive covers the entire bottom surface of each linear reflective element.

16. The reflector of claim 14, wherein the adhesive seals the edges and bottom surface of the linear reflective elements.

17. The reflector of claim 14, wherein the adhesive fills in the gaps between the plurality of linear reflective elements.

18. (canceled)

19. The reflector of claim 13, wherein portions of the reflector tray that comprise the combination of the reflector tray and the linear reflective elements have a stiffness greater than the portions of the reflector tray positioned between the linear reflective elements.

20. The reflector of claim 13, wherein the linear reflective elements are mirrors.

21. The reflector of claim 13, wherein the reflector tray comprises sheet metal.

22. The reflector of claim 13, wherein the reflector has a free state and a bent state and the energy stored in the reflector in the bent state tends to bias the reflector to re-achieve the free state.

23. The reflector of claim 13, wherein the tray comprises features that engage in a self-locking manner with complementary features in a support structure of the solar energy collector.
